(19) United States
(12) Patent Application Publication
(10) Pub. No.: US 2025/0338386 A1
(43) Pub. Date: Oct. 30, 2025

(54) MAINBOARD, METHOD FOR FORMING IMMERSED MAINBOARD, AND POWER SUPPLY MODULE

(71) Applicant: SHANGHAI METAPWR ELECTRONICS CO., LTD, Shanghai (CN)

(72) Inventors: Shouyu HONG, Shanghai (CN); Hongxiu LIU, Shanghai (CN); Xingqiang CHEN, Shanghai (CN); Jianhong ZENG, Shanghai (CN)

(73) Assignee: SHANGHAI METAPWR ELECTRONICS CO., LTD, Shanghai (CN)

(21) Appl. No.: 19/193,992

(22) Filed: Apr. 30, 2025

(30) Foreign Application Priority Data
Apr. 30, 2024 (CN) 202410541899.1
Aug. 24, 2024 (CN) 202411169669.3

(51) Int. Cl. H05K 1/02; H05K 1/03; H05K 1/14; H05K 3/30; H05K 3/34

(52) U.S. Cl. CPC H05K 1/0201; H05K 1/032; H05K 1/141; H05K 3/303; H05K 3/341; H05K 2201/0104; H05K 2201/10189; H05K 2201/10212; H05K 2203/1338

(57) ABSTRACT

A mainboard includes at least one power supply module and a mainboard body. The power supply module is arranged on the mainboard body. The power supply module comprises at least one surface-mounted element, a carrier plate, and an insulating layer. The carrier plate is provided with a first surface and a second surface which are opposite to each other, and the surface-mounted element is arranged on the first surface and the second surface. The insulating layer is formed in a chemical vapor deposition mode; a gap is formed between the surface-mounted element and the carrier plate, the gap is not completely filled with the insulating layer, and the insulating layer is further at least partially arranged on the surface of the space where the gap is located.

### CROSS-REFERENCE TO RELATED APPLICATION

This application claims the priority benefit of China application serial no. CN202410541899.1 filed on Apr. 30, 2024, and China application serial no. CN202411169669.3 filed on Aug. 24, 2024. The entirety of the above-mentioned patent application is hereby incorporated by reference herein and made a part of this specification.

### BACKGROUND

### Description of Related Art

Along with increasingly vigorous requirements of various artificial intelligence, data processing and the like, the computing capability of various board cards is continuously improved, and the power consumption of the computing chip is increased year by year. Meanwhile, due to the fact that the computing units are extremely high in size limitation, higher and higher requirements are provided for the occupied area, heat dissipation and the like of the energy processing unit.

In the prior art, in order to reduce the occupied area of the power processing unit, the three-dimensional (3D) stacked structure becomes a trend, but the 3D stacked structure is exposed in the environment, and pollutants such as dust, conductive particles, liquid and the like in the environment are prone to causing a short circuit risk between the metal electrodes of the 3D stacked device in the space.

Moreover, in order to improve heat dissipation performance, immersion cooling (single-phase immersion and dual-phase immersion cooling) becomes a main mode of cooling. Immersion cooling is carried out due to the fact that some conductive particles, such as solder balls from the surface of the printed circuit board assembly (PCBA), are easily mixed in the liquid. The conductive particles, along with the flow of liquid, may create a circuit bridging between adjacent electrodes, resulting in some functional faults, even causing some sub-disaster, causing the power module, computing chip to fail or even burn out.

In order to solve the problem, the surface of the PCBA usually needs to be coated with a three-proofing paint so as to play a role in surface insulation. However, due to the fact that when the 3D stacked structure is used, a common surface insulation mode, such as spraying three-proofing paint and the like, can have a shadow area. If immersion coating is adopted, and the risk of polluting on various connecting terminals can exist.

### SUMMARY

In view of the above, one of the objectives of the application is to provide a mainboard for immersion, comprising:
at least one power supply module and a mainboard body, wherein the at least one power supply module is arranged on the mainboard body.

The power supply module comprises:
at least one surface-mounted element;
a carrier plate, wherein the carrier plate is provided with a first surface and a second surface which are opposite to each other, and the surface-mounted element is arranged on the first surface and/or the second surface;
an insulating layer which is at least partially arranged on the pin of the surface-mounted element and/or the surface of the connecting solder joint between the pin and the carrier plate;
wherein the mainboard body faces to the second surface of the carrier plate; the insulating layer is formed in a chemical vapor deposition mode; a gap is formed between the surface-mounted element and the carrier plate, the gap is not completely filled with the insulating layer, and the insulating layer is further at least partially arranged on the surface of the space where the gap is located.

Preferably, the insulating layer has an average thickness of less than 10 μm.

Preferably, an elongation of the insulating layer is greater than 20%.

Preferably, the mainboard further comprises a connector, and the connector is arranged on the second surface.

Preferably, the carrier plate is the upper carrier plate, the mainboard further comprises a lower carrier plate, and the lower carrier plate faces to the second surface of the carrier plate.

Preferably, two ends of the connector are respectively connected with the upper carrier plate and the lower carrier plate.

Preferably, the mainboard further comprises a magnetic element, and pins of the magnetic element are respectively connected with the lower carrier plate and the upper carrier plate.

Preferably, a material of the insulating layer comprises parylene.

Preferably, a melting point of the material of the insulating layer is greater than 260° C.

Preferably, micro-protrusions are arranged on the surface of the insulating layer.

Preferably, the micro-protrusions are formed by adjusting process conditions of chemical vapor deposition.

Preferably, the mainboard body comprises a third surface and a fourth surface which are opposite to each other, and the third surface faces the second surface of the carrier plate.

Preferably, the mainboard further comprises a computing chip, the computing chip is arranged on the third surface of the mainboard body, and at least one of the power supply modules is arranged on the fourth surface of the mainboard body.

Preferably, the mainboard further comprises a connector, and the connector is arranged on the fourth surface of the mainboard body.

Preferably, the mainboard further comprises a supporting heat dissipation assembly, and the supporting heat dissipation assembly is in “[ ]” shape and is arranged on the third surface of the mainboard body.

Preferably, the method for forming the mainboard comprises the steps:
Step 1, performing a chemical vapor deposition process on a power supply module to form the insulating layer;
Step 2, assembling the processed power supply module to a mainboard.

Preferably, the method for forming the mainboard comprises the steps of:
Step 1, mounting at least one power supply module to a mainboard body to form a mainboard;
Step 2, performing a chemical vapor deposition process on the mainboard to form the insulating layer.

A power supply module, comprising:
at least one surface-mounted element;
at least two carrier plates, wherein the carrier plates are vertically stacked, the carrier plate is provided with a first surface and a second surface which are opposite, and the surface-mounted element is at least arranged between the two carrier plates;
an insulating layer which is at least partially arranged on the pin of the surface-mounted element and/or the surface of the connecting solder joint between the pin and the carrier plate;
the insulating layer is formed in a chemical vapor deposition mode, a gap is formed between the surface-mounted element and the carrier plate, the gap is not completely filled with the insulating layer, and the insulating layer is further at least partially arranged on the surface of the space where the gap is located.

Compared with the prior art, the application has the following beneficial effects:

According to the power module provided by the application, the risk of short circuit between electrodes caused by pollutants such as dust, conductive particles and liquid in the environment can be effectively prevented. In addition, the insulating layer of the mainboard is formed in a chemical vapor deposition mode, the problem that a shadow area caused by spraying cannot cover an insulating layer is avoided, and the problem of pollution connecting terminals caused by immersion is also avoided. Meanwhile, the insulating layer is extremely thin, has good heat dissipation performance, and does not completely fill the gap.

### BRIEF DESCRIPTION OF THE DRAWINGS

FIG. 1 is a partial schematic diagram of a power supply module.

FIG. 2, FIG. 3, and FIG. 4 are examples of a power supply module.

FIG. 5 is a top view of the mainboard.

FIG. 6 is a bottom view of the mainboard.

FIG. 7 is a schematic diagram of a mainboard and a supporting heat dissipation assembly.

FIG. 8 is a bottom view of another embodiment of the mainboard.

### DESCRIPTION OF THE EMBODIMENTS

The technical solutions in the embodiments of the present application are clearly and completely described below with reference to the accompanying drawings in the embodiments of the present application However, the described embodiments are only a part but not all of the embodiments of the present application on the basis of the embodiments of the present application, all other embodiments obtained by a person of ordinary skill in the art without creative efforts shall fall within the protection scope of the present application.

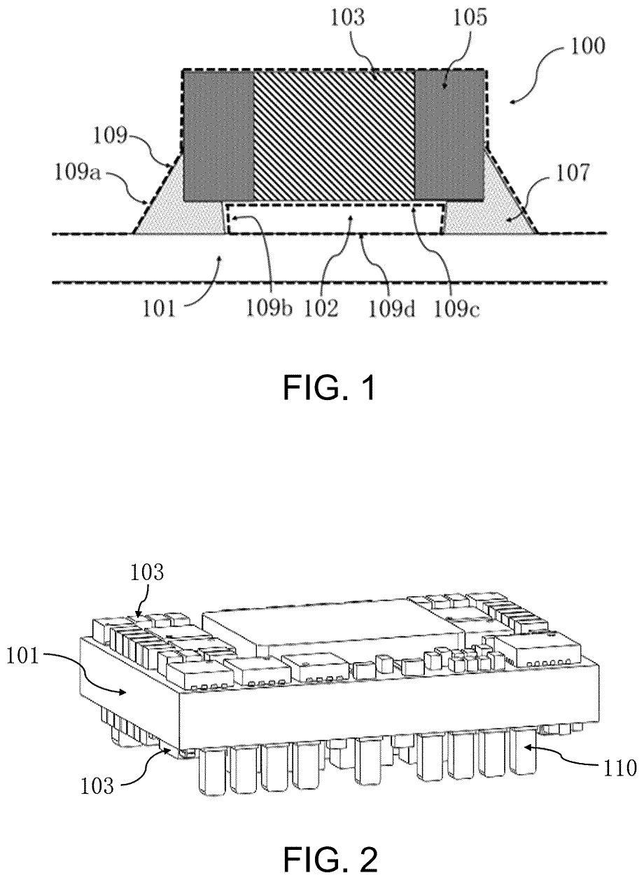

FIG. 1 is a partial schematic diagram of a power supply module. As shown in FIG. 1, the power supply module 100 comprises at least one surface-mounted element 103, an insulating layer 109 and a carrier plate 101; the carrier plate 101 is provided with a first surface and a second surface which are opposite to each other, and the surface-mounted element 103 is arranged on the first surface and/or the second surface; the insulating layer 109 is at least partially arranged on the surface of the pin 105 of the surface-mounted element and/or the surface of the connecting solder joint 107 between the pin 105 and the carrier plate 101; the second surface is a surface facing the mainboard body 200 (mentioned below), the first surface and the second surface are only used for expressing relative positions.

The insulating layer 109 is formed by chemical vapor deposition (CVD). The surface-mounted element 103 is provided on the carrier plate 101 by means of a pin 105 thereof, and then the surface-mounted element 103 is welded to the carrier plate 101 by means of reflow soldering. Optionally, as shown in FIG. 1, the insulating layer is disposed on the entire surface of the surface-mounted element 103, the entire surface of the pin 105 of the surface-mounted element 103, the entire surface of the connecting solder joint 107 between the pin 105 and the carrier plate 101, and the first and second surfaces of the carrier plate 101.

Preferably, the insulating layer 109 is at least arranged on the surface of the pin 105 of the surface mounting element, the connecting solder joint 107 between the pin 105 and the carrier plate 101.

Optionally, the insulating layer 109 includes insulating layers 109a, 109b, 109c and 109d disposed on surfaces of different positions. The insulating layer 109a of the present application can be disposed on an outer surface of the surface-mounted element 103 and the connecting solder joint 107. The insulating layer 109b can also be arranged on the inner surface of the connecting solder joint 107. The insulating layer 109c can also be arranged on the inner surface of the surface attaching element 103, and the insulating layer 109d can also be arranged on the inner surface located between the surface attaching elements of the carrier plate 101. The insulating layer 109 formed by chemical vapor deposition can be uniformly arranged on the surface of each element.

Preferably, the average thickness of the insulating layer is less than 10 μm and the extension rate of the insulating layer is greater than 20%. A gap 102 is provided between the surface-mounted element 103 and the carrier plate 101, and the gap 102 is not completely filled by the insulating layer. The thickness is less than 10 μm, insulation protection can be achieved, meanwhile, heat dissipation can be improved, and the gap 102 cannot be completely filled. Therefore, during reflow soldering, it's beneficial to absorb the expansion deformation of the solder joint; and effectively prevent the solder bridging caused by interface peeling due to the volumetric expansion of the solder between the adjacent pins; and meanwhile, the thin insulating layer cannot be formed by the method in the prior art. Specifically, the surface-mounted element 103 is arranged on the second surface facing the mainboard body 200. Extremely thin coating is conducive to quick repairs, and can be rapidly removed through plasma treatment, laser ablation, mechanical decapping and other modes; the removal procedure can be completed within minutes. Compared to traditional conformal coating removal methods—which typically require over 20 hours of soaking and consume large amounts of solvent—this approach significantly reduces repair costs, processing time, and environmental pollution.

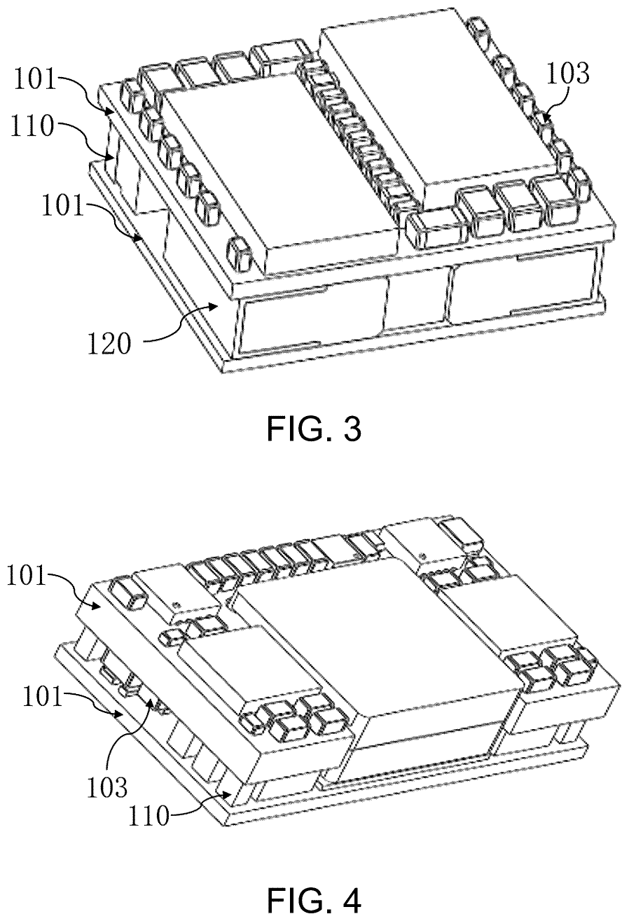

Optionally, the insulating layer 109 is at least partially disposed on a surface of a space where the gap is located. FIG. 1 shows only a situation where the insulating layer completely covers the surface of the space where the gap 102 is located. For example, the insulating layer only covers the inner surface of the surface-mounted element 103 and the inner surface of the connecting solder joint 107. FIG. 2 illustrates an example of a power module 100. As shown in FIG. 1, the power supply module 100 further comprises a connector 110, and the connector 110 is arranged on a second surface (equivalent to a lower surface in the figure) of the carrier plate 101 and is used for realizing electrical connection of at least one surface-mounted element 103. In this example, the surface-mounted element 103 is disposed on a first surface (i.e., an upper surface) and a second surface (i.e., a lower surface in the figure) of the carrier plate 101. In the example, due to the fact that the insulating layer formed by chemical vapor deposition is adopted, the risk of short circuit between electrodes caused by pollutants such as dust, conductive particles and liquid in the environment can be effectively prevented. Moreover, a shadow area exists between the carrier plate 101 and the mainboard body 200, so that the surface-mounted element 103 arranged between the carrier plate 101 and the mainboard body 200 cannot be well protected, and when the three-proofing paint is sprayed, due to the existence of the shadow area, the spraying effect of the three-proofing paint is poor. When using the immersion coating method, there is also a risk of contaminating various types of connection terminals. However, the insulating layer formed by chemical vapor deposition can well solve the problems.

In other examples, the power supply module 100 at least comprises two carrier plates 101, the carrier plates 101 are vertically stacked, and the surface-mounted elements 103 are at least arranged between the carrier plates 101. As shown in FIG. 3 and FIG. 4, the number of the carrier plates 101 of the power supply module 100 is two. Optionally, the surface-mounted element 103 is provided on both a first surface (an exemplary upper surface) and a second surface (an exemplary representation lower surface) of the upper carrier plate 101, and a surface-mounted element 103 is arranged on the first surface (exemplary representation upper surface) of the lower carrier plate 101; the height spacing between the surface-mounted element 103 on the lower surface of the upper carrier plate and the surface-mounted element 103 on the upper surface of the lower carrier plate is less than or equal to 0.5 mm; and further optionally, the spacing is less than or equal to 0.3 mm; and further preferably, the spacing is less than or equal to 0.1 mm. Further, metal electrodes are arranged on the surface of the surface-mounted element 103 disposed on the second surface (exemplary representation lower surface) of the upper carrier plate 101 and the surface of the surface-mounted element 103 on the upper surface of the lower carrier plate. The projections of the metal electrodes in the vertical direction at least partially overlapped; the spacing between the exposed metal electrodes is less than or equal to 0.5 mm; and further optionally, the spacing is less than or equal to 0.3 mm; and further preferably, the spacing is less than or equal to 0.1 mm. In the example, due to the fact that the insulating layer formed by chemical vapor deposition is adopted, the risk of short circuit between electrodes caused by pollutants such as dust, conductive particles and liquid in the environment can be effectively prevented. Moreover, although the surface-mounted element between the upper carrier plate 101 and the lower carrier plate has a shadow area, the surface-mounted element 103 can be well protected by the insulating layer to prevent short-circuit or pollution due to the fact that the insulating layer is formed in a chemical vapor deposition mode.

Optionally, as shown in FIG. 3 and FIG. 4, a second surface (an example shows a lower surface) of the lower carrier plate 101, and a bonding pad arranged on the surface is used for external connection. In order to prevent the bonding pad from being covered by the insulating layer in the chemical vapor deposition process, the bonding pad is protected in a film pasting mode and the like. In order to enhance the protection effect, at least the outermost pad is in the form of a solder mask defined pad. Furthermore, at least part of the bonding pads in the interior can be in the form of a non-solder mask defined pad, so that sufficient exhaust is facilitated in the external connection welding process, and defects such as tin beads and cavities are prevented.

Optionally, two ends of the connector 110 are respectively connected to the upper carrier plate 101 and the lower carrier plate 101.

Optionally, the power supply module 100 further comprises a magnetic element 120, and pins of the magnetic element 120 are respectively connected to the upper carrier plate 101 and the lower carrier plate 101. The magnetic element 120 is a magnetic core.

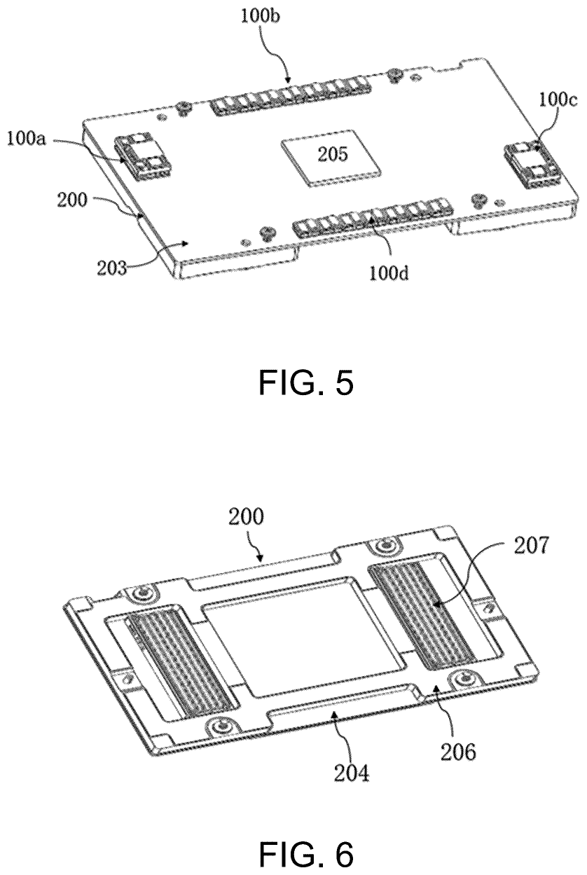

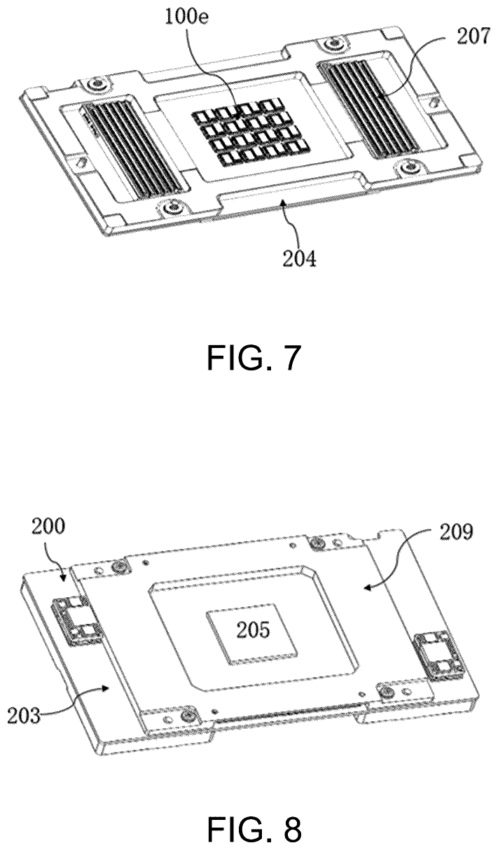

FIG. 5 to FIG. 8 show schematic diagrams of a mainboard for immersion. As shown in FIG. 5 to FIG. 8, the mainboard for immersion comprises at least one power supply module 100 and a mainboard body 200, the at least one power supply module 100 is arranged on the mainboard body 200, and the mainboard body 200 is opposite to the second surface of the carrier board 101. The power supply module 100 is any power supply module shown in FIG. 1 to FIG. 4.

A shadow area is also formed between the carrier plate 101 of the power supply module 100 and the mainboard body 200, so that the spraying type in the prior art cannot cover the insulating layer in the shadow area, and the insulating layer can solve the problem.

Optionally, at least two carrier plates in the power supply module 100 are vertically stacked and then are arranged on the mainboard body 200. Due to the fact that a shadow area is also formed between the stacked carrier plates 101 of the power supply modules 100, the spraying type in the prior art cannot cover the insulating layer in the shadow area, and the insulating layer can solve the problem.

The mainboard body 200 comprises a third surface 203 and a fourth surface 204 which are opposite to each other, and the third surface 203 is opposite to the second surface of the carrier plate 101. The mainboard body 200 comprises a first side edge, a second side edge, a third side edge and a fourth side edge which are sequentially connected. The power supply module 100 comprises a first front-stage power supply module 100a, a first rear-stage power supply module 100b, a second front-stage power supply module 100c and a second rear-stage power supply module 100d. The first front-stage power supply module 100a is arranged close to the first side edge, the first rear-stage power supply module 100b is arranged close to the second side edge, the second front-stage power supply module 100c is arranged close to the third side edge, and the second rear-stage power supply module 100d is arranged close to the fourth side edge. The power supply module 100 further comprises a computing chip module 205, and the computing chip module 205 is arranged on a third surface 203 of the mainboard body 200, and is specifically arranged in the middle of the third surface. As shown in FIG. 6, the mainboard further comprises a connector 207, the connector 207 is arranged on the fourth surface 204 of the mainboard body; and the connector 207 is an external connector of the computing chip module 205. The mainboard further comprises a supporting heat dissipation assembly 209 and a supporting assembly 206, and the supporting heat dissipation assembly 209 is in an “[ ]” shape and is arranged on the third surface 203 of the mainboard body; the supporting assembly 206 is of a frame structure and is arranged on the fourth surface 204 of the mainboard body; the power supply module 100e can also be arranged on the fourth surface 204 of the mainboard body; the frame structure of the supporting assembly 206 is in the shape of a “II” shape, and the power supply module 100e and the connector 207 are respectively arranged at the opening of the frame structure.

When the connector 207 is used for chemical vapor deposition of the insulating layer, the connector 207 can be protected, for example, through a film pasting mode, so that the connector 207 is not polluted. But immersion type dip coating in the prior art; even if the connector is attached to the surface of the connector, due to the immersion mode, the risk of polluting the connecting terminal can also exist. In addition, the power supply module and the connector are arranged on the same surface, and the arrangement of the traditional immersion type three-proofing paint cannot be realized.

The application further provides a forming method of the mainboard. The forming method comprises the steps:

Providing at least one power supply module and at least one mainboard body, wherein the power supply module is any one of the power supply modules 100 shown in FIG. 1 to FIG. 4, and the mainboard body is any mainboard body 200 shown in FIG. 5 to FIG. 8.

Step 1, performing a chemical vapor deposition process on a power supply module 100 to form the insulating layer 109;

Step 2, carrying the processed power supply module 100 to a mainboard body 200.

Or,
Step 1, mounting at least one power supply module 100 to a mainboard body 200 to form a mainboard;
Step 2, performing a chemical vapor deposition process on the mainboard to form the insulating layer 109.

The method further comprises the following steps: implementing a protection step on the connector 207, specifically, pasting a film on the surface of the connector 207, wherein the protection step is implemented before the chemical vapor deposition process.

The steps further comprise: removing the insulating layer on the surface of the non-protection area, specifically, removing the insulating layer on the surface of the non-protection area in a laser ablation mode, wherein the non-protection area is an area without insulation protection, for example, the surface of heating chip in the power supply module, and after the step 2, the removal step can further increase the heat dissipation effect.

In the above steps, before the chemical vapor deposition process is carried out, the method further comprises a pre-cleaning step, namely cleaning the surface of the power supply module 100 or the surface of the mainboard carrying the power supply module so as to remove residues, tin beads, dust and the like of the soldering flux so as to prevent the bonding force of the insulating layer formed by CVD and the substrate from being insufficient, interface peeling occurs during reflow soldering, and short circuits caused by solder bridging between opposite electrodes. Furthermore, a plasma surface treatment step is added after the cleaning treatment, so that the interface bonding force is further improved.

The material of the insulating layer comprises parylene, and the specific model is at least one of Type C, Type D, Type E, Type F and Type N. The insulating property of the parylene is excellent, the production process is stable; and the insulating layer grows layer by layer with the molecular thickness, so that the insulating layer can be used for treating the safety reinforced insulation with extremely thin thickness, such as less than 50 μm. Besides, the surface creepage distance required by the safety insulation can be greatly reduced, and due to the extremely thin thickness, the conduction thermal resistance of the module when the heat sink is installed outside can be reduced. In addition to high insulation performance, the poly-p-xylene material also has excellent compactness, and can further enhance the weather resistance of the product, such as moisture-heat resistance, corrosion resistance and the like. Meanwhile, the dielectric constant of the parylene material is low, the dielectric constant of the paraxylene material is generally smaller than 4 and the dielectric constant of the immersed cooling liquid is close, and local electric field distortion caused by material mutation can be effectively avoided. In addition, the melting point of the material of the insulating layer is greater than 260° C. Especially in the first method, since the melting point is greater than 260° C., the temperature of reflow soldering does not affect the insulating layer. Preferably, micro-protrusions are arranged on the surface of the insulating layer, the micro-protrusions are formed by adjusting process conditions of chemical vapor deposition, the micro-protrusions can increase the surface area, and heat dissipation is facilitated.

The “equal” or “same” or “equal to” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%. In addition, relational terms such as first and second are used herein to distinguish one entity or operation from another entity or operation, and do not necessarily require or imply that there is any such actual relationship or sequence between these entities or operations. Moreover, the terms “comprising,” “including,” or any other variation thereof are intended to cover a non-exclusive inclusion, such that a process, method, article, or device that includes a series of elements includes not only those elements, but also other elements that are not explicitly listed, or elements inherent to such a process, method, article, or device. In the absence of more restrictions, a statement “comprising one. A defined element does not preclude the existence of additional identical elements in the process, method, article, or device that includes the element.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A mainboard for immersion, comprising:
at least one power supply module and a mainboard body, wherein the at least one power supply module is arranged on the mainboard body;
wherein the power supply module comprises:
at least one surface-mounted element;
a carrier plate, wherein the carrier plate is provided with a first surface and a second surface which are opposite to each other, and the at least one surface-mounted element is arranged on the first surface and the second surface;
an insulating layer which is at least partially arranged on a pin of the at least one surface-mounted element and a surface of a connecting solder joint between the pin and the carrier plate;
wherein the mainboard body faces to the second surface of the carrier plate; the insulating layer is formed in a chemical vapor deposition mode; a gap is formed between the at least one surface-mounted element and the carrier plate, the gap is not completely filled with the insulating layer, and the insulating layer is further at least partially arranged on a surface of a space where the gap is located.

2. The mainboard of claim 1, wherein the insulating layer has an average thickness of less than 10 μm.

3. The mainboard of claim 1, wherein an elongation of the insulating layer is greater than 20%.

4. The mainboard of claim 1, further comprises a connector, and the connector is arranged on the second surface.

5. The mainboard of claim 4, wherein the carrier plate is an upper carrier plate, the mainboard further comprises a lower carrier plate, and the lower carrier plate faces to the second surface of the carrier plate.

6. The mainboard of claim 5, wherein two ends of the connector are respectively connected with the upper carrier plate and the lower carrier plate.

7. The mainboard of claim 6, further comprises a magnetic element, and pins of the magnetic element are respectively connected with the lower carrier plate and the upper carrier plate.

8. The mainboard of claim 1, wherein a material of the insulating layer comprises parylene.

9. The mainboard of claim 1, wherein a melting point of the material of the insulating layer is greater than 260° C.

10. The mainboard of claim 1, wherein micro-protrusions are arranged on the surface of the insulating layer.

11. The mainboard of claim 10, wherein the micro-protrusions are formed by adjusting process conditions of chemical vapor deposition.

12. The mainboard of claim 1, wherein the mainboard body comprises a third surface and a fourth surface which are opposite to each other, and the third surface faces the second surface of the carrier plate.

13. The mainboard of claim 12, further comprises a computing chip, wherein the computing chip is arranged on the third surface of the mainboard body, and at least one of the power supply modules is arranged on the fourth surface of the mainboard body.

14. The mainboard of claim 13, further comprises a connector, and the connector is arranged on the fourth surface of the mainboard body.

15. The mainboard of claim 13, further comprises a supporting heat dissipation assembly, wherein the supporting heat dissipation assembly is in “ [symbol] ” shape, and is arranged on the third surface of the mainboard body.

16. A method for forming the mainboard of claim 1, comprising:
step 1, performing a chemical vapor deposition process on a power supply module to form the insulating layer;
step 2, assembling the processed power supply module to a mainboard.

17. A method for forming the mainboard of claim 1, comprising:
step 1, mounting at least one power supply module to a mainboard body to form a mainboard;
step 2, performing a chemical vapor deposition process on the mainboard to form the insulating layer.

18. A power supply module, comprising:
at least one surface-mounted element;
at least two carrier plates, wherein the at least two carrier plates are vertically stacked, each of the at least two carrier plates is provided with a first surface and a second surface which are opposite, and the surface-mounted element is at least arranged between the at least two carrier plates; and
an insulating layer which is at least partially arranged on a pin of the at least one surface-mounted element and a surface of a connecting solder joint between the pin and each of the at least two carrier plates;
wherein the insulating layer is formed in a chemical vapor deposition mode, a gap is formed between the at least one surface-mounted element and each of the at least two carrier plates, the gap is not completely filled with the insulating layer, and the insulating layer is further at least partially arranged on a surface of a space where the gap is located.
